(19) United States
(12) Patent Application Publication
(10) Pub. No.: US 2026/0002981 A1
(43) Pub. Date: Jan. 1, 2026

(54) SOCKET DOWNSTOP CREEP DETECTION WITH IN-LINE ELECTRICAL MEASUREMENTS

(71) Applicant: INTERNATIONAL BUSINESS MACHINES CORPORATION, ARMONK, NY (US)

(72) Inventors: NOAH SINGER, WHITE PLAINS, NY (US); JOHN TOROK, POUGHKEEPSIE, NY (US); JOHN S. WERNER, FISHKILL, NY (US); LUKE L. JENKINS, POUGHKEEPSIE, NY (US); ARKADIY O. TSFASMAN, WAPPINGERS FALLS, NY (US)

(21) Appl. No.: 18/756,002

(22) Filed: Jun. 27, 2024

(51) Int. Cl. G01R 31/28; G01R 1/04; H05K 1/14

(52) U.S. Cl. CPC G01R 31/2853; G01R 1/0466; H05K 1/141; H05K 2201/10189

(57) ABSTRACT

Methods, systems, and products for socket downstop creep detection includes enabling a current source on a creep detection circuit coupled to one or more creep detection pins within a PCB socket coupled to a module, tracking one or more resistance values associated with the creep detection circuit, and detecting socket downstop creep associated with the module based on determining that the one or more resistance values have changed by more than a threshold amount.

### BACKGROUND

### Field of the Disclosure

The field of the disclosure is data processing, or, more specifically, methods, systems, and products for socket downstop creep detection.

### Description of Related Art

Sockets on a circuit board include mechanical and electrical connections to couple a computer module (such as a processor) to the circuit board without soldering. Sockets often include downstops that act to prevent the module from compressing the electrical pins past a certain point. That is, modules coupled to a socket experience continuous mechanical stress and compression, and the downstops included in the socket keep the module in proper contact with the circuit board. The socket downstops, which are under constant mechanical stress, may experience creep, causing the downstops to compress and allow the module to come closer to the circuit board. When downstop creep occurs, the processor and/or the contact pins of the socket are over compressed and may misalign with the contact pads of the module or get damaged.

### SUMMARY

Methods, apparatus, and systems for socket downstop creep detection according to various embodiments are disclosed in this specification. In accordance with one aspect of the present disclosure, a method of socket downstop creep detection includes enabling a current source on a creep detection circuit coupled to one or more creep detection pins within a printed circuit board (PCB) socket coupled to a module, tracking one or more resistance values associated with the creep detection circuit, and detecting socket downstop creep associated with the module based on determining that the one or more resistance values have changed by more than a threshold amount.

In accordance with another aspect of the present disclosure, a system for socket downstop creep detection may include a module having multiple contact pads, a printed circuit board (PCB) comprising: a socket for receiving the module, where the socket includes multiple pins configured to contact the multiple contact pads of the module when the module is coupled to the socket, and a creep detection circuit configured to detect a threshold amount of creep within the socket, where one or more of the pins are creep detection pins coupled to the creep detection circuit; the system also includes a controller configured to receive data from the creep detection circuit, and a database configured to store data related to the creep detection circuit.

The foregoing and other objects, features and advantages of the disclosure will be apparent from the following more particular descriptions of exemplary embodiments of the disclosure as illustrated in the accompanying drawings wherein like reference numbers generally represent like parts of exemplary embodiments of the disclosure.

### BRIEF DESCRIPTION OF THE DRAWINGS

FIG. 1 shows an example line drawing of a system configured for socket downstop creep detection in accordance with embodiments of the present disclosure.

FIG. 2 is a block diagram of an example network diagram configured for socket downstop creep detection according to some embodiments of the present disclosure.

FIG. 3 is a block diagram of an example computing environment configured for socket downstop creep detection according to some embodiments of the present disclosure.

FIG. 4 is a flowchart of an example method for socket downstop creep detection according to some embodiments of the present disclosure.

FIG. 5 is a flowchart of another example method for socket downstop creep detection according to some embodiments of the present disclosure.

### DETAILED DESCRIPTION

In accordance with one aspect of the present disclosure, a method of socket downstop creep detection includes enabling a current source on a creep detection circuit coupled to one or more creep detection pins within a printed circuit board (PCB) socket coupled to a module, tracking one or more resistance values associated with the creep detection circuit, and detecting socket downstop creep associated with the module based on determining that the one or more resistance values have changed by more than a threshold amount. Such an embodiment allows for the detection of downstop creep before it has a chance to damage or negatively affect the system.

In another embodiment, tracking the one or more resistance values includes, iteratively at a set interval: measuring one or more voltages across the creep detection circuit; and calculating, based on the one or more voltages, the one or more resistance values associated with the creep detection circuit. Such an embodiment provides for a method of effectively tracking resistance across the creep detection pins to in turn detect the presence of creep in the socket downstops.

In another embodiment, the method further includes storing the one or more resistance values each time they are calculated. Such an embodiment for the ability to compare current resistance values with previous ones in order to see how much the resistance has changed over time, which may indicate whether or not creep has occurred.

In another embodiment, determining that the one or more resistance values have changed by more than the threshold amount includes comparing the one or more resistance values to previously recorded resistance values associated with the creep detection circuit. Such an embodiment allows for the detection of creep based on a predetermine threshold that may be selected by a user or automatically set.

In another embodiment, the method further includes generating a notification responsive to detecting socket downstop creep associated with the module. Such an embodiment allows user or admins to be notified of the presence of creep, so that the socket may be repaired before damage or failures occur.

In another embodiment, the method further includes, responsive to detecting the socket downstop creep, shifting workload away from an area experiencing the socket downstop creep. Such an embodiment provides for a method of preventing errors by utilizing areas of the socket that have not yet experienced creep.

In another embodiment, the workload is shifted to one of: another core on the module, another processor on the module, and another module. Such an embodiment provides a method of moving workload to various other locations to avoid potential errors associated with the detected downstop creep.

In another embodiment, the method further includes generating a strain map across the module using the one or more resistance values. Such an embodiment provides a map that may demonstrate which parts of the socket is experiencing creep or may experience creep in the future.

In another embodiment, detecting socket downstop creep associated with the module is based on the one or more resistance values decreasing by a threshold amount. Such an embodiment provides one method of detecting creep with a certain type of creep detection pin.

In another embodiment, detecting socket downstop creep associated with the module is based on the one or more resistance values exceeding a threshold value. Such an embodiment provides another method of detecting creep with another type of creep detection pin.

In accordance with another aspect of the present disclosure, a system for socket downstop creep detection includes a module having multiple contact pads, a printed circuit board (PCB) comprising: a socket for receiving the module, where the socket includes multiple pins configured to contact the multiple contact pads of the module when the module is coupled to the socket, and a creep detection circuit configured to detect a threshold amount of creep within the socket, where one or more of the pins are creep detection pins coupled to the creep detection circuit; the system also includes a controller configured to receive data from the creep detection circuit, and a database configured to store data related to the creep detection circuit. Such an embodiment allows for the detection of downstop creep before it has a chance to damage or negatively affect the system.

In another embodiment, the data stored in the database comprises resistance measurements associated with the creep detection circuit. Such an embodiment provides a method for storing resistance data that may be used for detecting creep in the future.

In another embodiment, the PCB includes multiple creep detection circuits associated with the socket, wherein each creep detection circuit is configured to monitor downstop creep in an area of the socket proximate to each creep detection circuit. Such an embodiment allows for the detection of creep in multiple different parts of the socket.

In another embodiment, the module includes one or more connections between one or more contact pads contacting the creep detection pins. Such an embodiment provides a mechanism for measuring the resistance across the creep detection pins in the creep detection circuit.

In another embodiment, the plurality of pins includes the creep detection pins and one or more contact pins configured to route signals between the module and the PCB. Such an embodiment allows the module to both carry out its normal functions while also allowing for creep detection in the socket.

In another embodiment, the creep detection pins are structurally different from the one or more contact pins. Such an embodiment allows for the detection of creep in one or more different ways independent of the form or design of the other contact pins included within the socket.

In another embodiment, the creep detection pins are configured to increase a surface area of the creep detection pins contacting one or more contact pads when the socket experiences creep. Such an embodiment allows for one method of detecting creep.

In another embodiment, each of the creep detection pins is configured to slip off of a contact pad when the socket experiences the threshold amount of creep. Such an embodiment allows for another method of detecting creep.

In another embodiment, downstop creep is measured by the creep detection circuit based on resistance measurements associated with the creep detection circuit. Such an embodiment allows for the detection of creep using a simple resistance-measuring creep detection circuit.

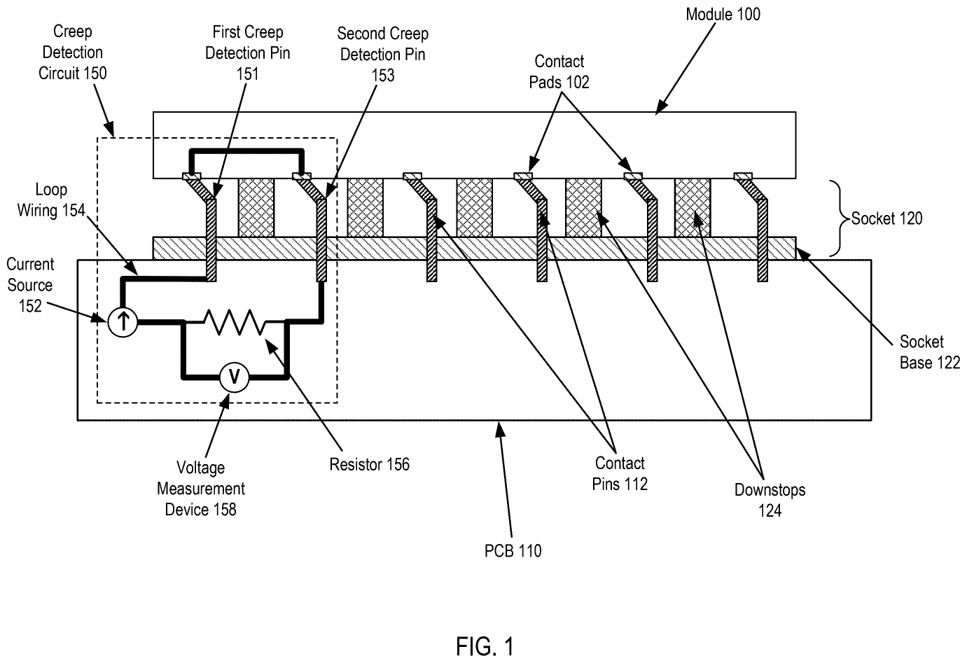

Exemplary methods, systems, and products for socket downstop creep detection in accordance with the present disclosure are described with reference to the accompanying drawings, beginning with FIG. 1. FIG. 1 sets forth an example line drawing of a system configured for socket downstop creep detection in accordance with embodiments of the present disclosure. The example system of FIG. 1 includes a PCB 110, a socket 120 on the PCB having a socket base 122 and multiple downstops 124, a module 100 coupled to the PCB through the socket of the PCB, and a creep detection circuit 150 included within the PCB and the module.

The example PCB may be configured to couple multiple different computer components to one another. Some components may be soldered onto the PCB while other components may be coupled to the PCB without soldering (such as through the use of a socket or some other electrical connection or mount). The example PCB of FIG. 1 includes multiple contact pins 112 that protrude away from the PCB through the socket 120.

The example socket 120 includes socket base 122 which is positioned on a top surface of the PCB 110. The socket 120 also includes one or more downstops 124 configured to prevent the module 100 from compressing (or bending) the contact pins 112 past a certain point. Because modules coupled to a socket experience continuous mechanical stress and compression forces, the downstops included in the socket keep the module in proper contact with the circuit board. The contact pins 112 protrude through the socket and are configured to contact the one or more contact pads 102 included in the module 100 when the module is coupled to the socket.

The example module 100 includes one or more contact pads 102 configured to contact the one or more contact pins 112 of the PCB when the module is coupled to the socket. The example module 100 may be a processor, a controller, a graphics processing unit, memory, or any other computer component configured to be coupled to the PCB through a socket.

Creep (a form of deformation) is the tendency of a solid material to undergo slow deformation when subjected to continued mechanical stress. Creep is typically more severe in materials that also experience increased levels of heat. The socket downstops, which are under constant mechanical stress, may experience creep, causing the downstops to compress and allow the module to come closer to the circuit board. When downstop creep occurs, the processor and/or the contact pins of the socket are over compressed and may misalign with the contact pads of the module or get damaged. For example, the module of FIG. 1 is properly coupled to the PCB through the socket. Even when properly coupled, the contact pins 112 deflect or bend slightly (while still contacting the contact pads 102) so that they remain in contact with the contact pads with a constant pressure. When the socket experiences creep, however, the contact pins 112 may break or may deflect or bend even more so than depicted in FIG. 1, which could cause the contact pins to slip off of (or become misaligned with) the contact pads 102, further causing errors, loss of signal, loss of module functionality, or other performance issues. Damaged contact pins 112 would require replacement of the PCB in an end-product, which may require a large cost of money or downtime for the system. Creep may occur evenly across the socket or may occur unevenly (where different downstops in the socket experience more creep than others), which could lead to chip cracking.

The example PCB 110 of FIG. 1 includes a creep detection circuit 150 configured to detect creep within the socket 120. The creep detection circuit includes a current source 152, loop wiring 154 running through the PCB and the module in a loop and coupled to a first creep detection pin 151 and a second creep detection pin 153, a resistor 156, and a voltage measurement device 158. The current source 152 is configured to send current around the creep detection circuit at a constant rate. The loop wiring is configured to allow the current from the current source to flow through the first creep detection pin into the module and then back through the second creep detection pin back into the PCB and to the resistor and voltage measurement device before looping back around. The creep detection circuit 150 is configured to measure the resistance across the first and second creep detection pins (151 and 153). Specifically, the voltage measurement device 158 is configured to continuously (or periodically at a predetermined interval) measure the voltage of the creep detection circuit. Because the current running through the circuit is constant, a change in voltage indicates a proportional change in resistance (because V=IR). By measuring the voltage and calculating the resistance across the creep detection pins, the creep detection circuit may keep track of any changes in resistance over time.

The creep detection pins (151 and 153) are configured to change in resistance as they experience downstop creep at the surround area of the socket. In one embodiment, the creep detection pins are configured to contact precise or relatively small contact pads within the module, so that any creep in the downstops would cause the creep detection pins to slip off the contact pads of the module, thereby causing a large increase in resistance. In such an embodiment, detecting socket downstop creep associated with the module is based on the measured resistance values across the creep detection pins exceeding a threshold value. In such an example, the threshold value may be selected as a value that may only be reached or exceeded if one or more of the creep detection pins move so that they are no longer in contact with a corresponding contact pad 102 in the module.

In another embodiment, the creep detection pins are configured to increase the surface area of contact between the pins and the contact pads, so that any creep in the downstops would cause the resistance value across the creep detection pins to decrease as more surface area of the pins come into contact with the contact pads. In such an embodiment, detecting socket downstop creep associated with the module is based on the measured resistance values across the creep detection pins decreasing by a threshold amount. In such an embodiment, the threshold amount of change in resistance may be selected according to a model or may be predetermined by a user.

In the example embodiment of FIG. 1, there is a single creep detection circuit included as part of the socket 120. In another embodiment, multiple creep detection circuits may be included at various positioned or locations within the socket, so as to monitor multiple different areas of the socket for downstop creep. Such an example is useful when downstop creep occurs unevenly across the socket. In the example embodiment of FIG. 1, a single module is coupled to socket 120. In another embodiment, multiple modules may be coupled to a single socket. In some embodiments, there may be a separate creep detection circuit corresponding to each module coupled to the socket. In another embodiment, there may be multiple creep detection circuits associated with each module coupled to the circuit.

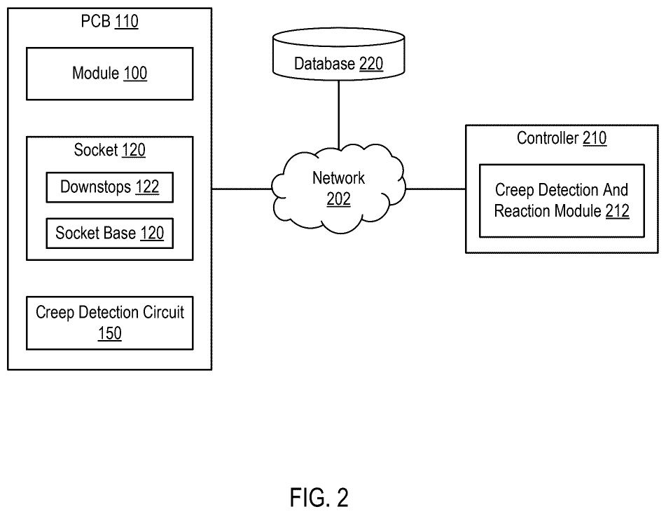

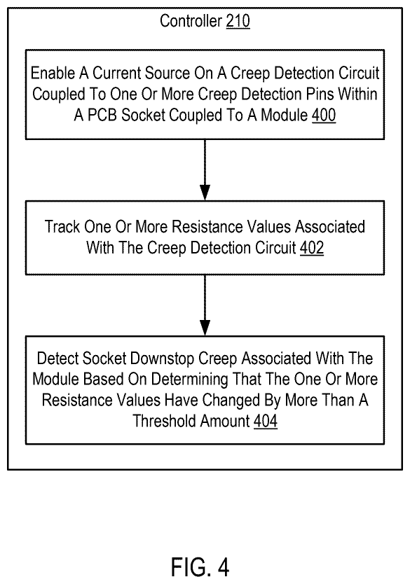

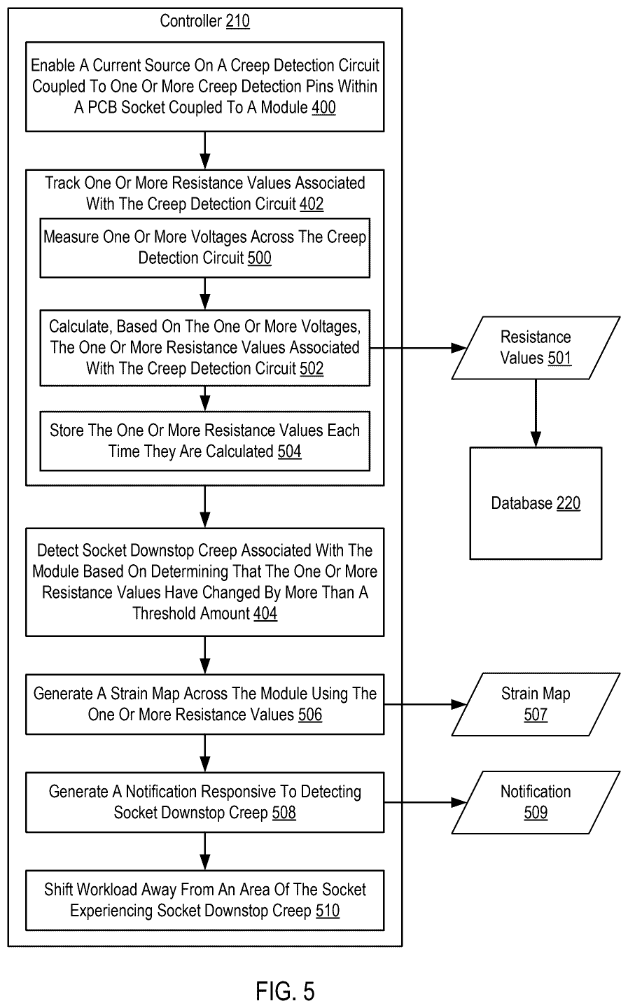

For further explanation, FIG. 2 sets forth a block diagram of a network diagram configured for socket downstop creep detection in accordance with embodiments of the present disclosure. The network diagram of FIG. 2 includes a network 202 configured to communicatively couple the PCB 110 of FIG. 1 with a database 220 and a controller 210. The example PCB 110 is may be the PCB of FIG. 1 or any other PCB configured with a creep detection circuit 150. The example network 202 may be any computer network configured to communicatively couple one or more computer systems or components. The example controller 210 is configured to carry out the example embodiments of the present disclosure (such as the methods depicted in FIG. 4 and FIG. 5). The controller may be a processor, a microcontroller, or any other controller configured to send, receive, or execute instructions. The example controller 210 is configured to operate the creep detection circuit and receive data (such as voltage or resistance measurements from the creep detection circuit). The example controller 210 is also configured to store the measured values associated with the creep detection circuit in the database 220. In the example embodiment of FIG. 2, the database, the controller, and the PCB are communicatively coupled via network 202. In another embodiment, the controller, the database, and the PCB are directly coupled within the same computer system.

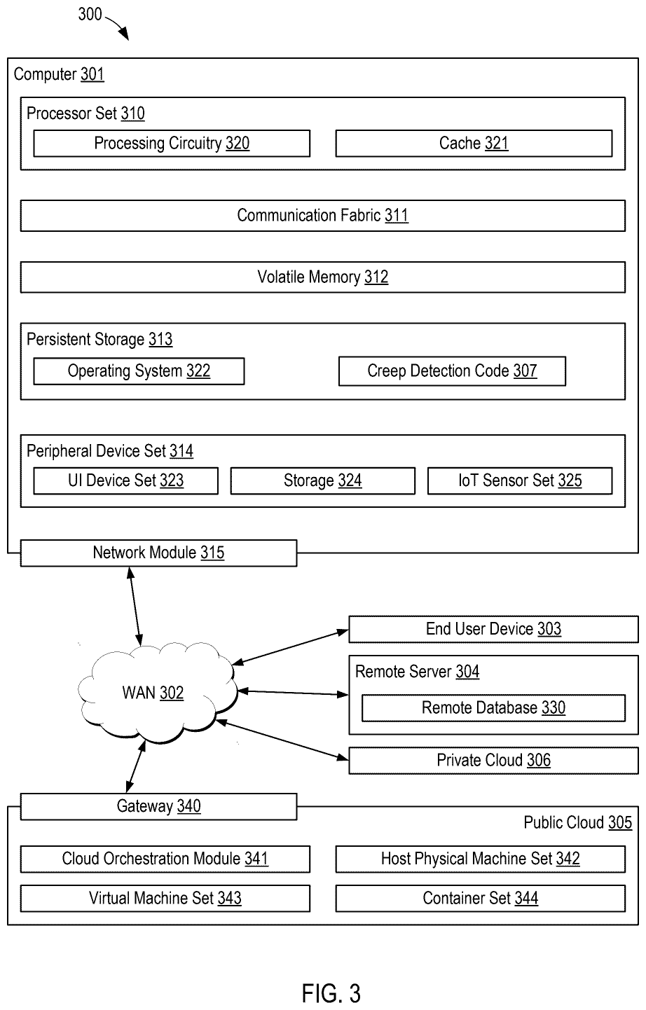

For further explanation, FIG. 3 sets forth a block diagram of computing environment 300 configured for socket downstop creep detection in accordance with embodiments of the present disclosure. Computing environment 300 contains an example of an environment for the execution of at least some of the computer code involved in performing the inventive methods, such as creep detection code 307. In addition to creep detection code 307, computing environment 300 includes, for example, computer 301, wide area network (WAN) 302, end user device (EUD) 303, remote server 304, public cloud 305, and private cloud 306. In this example embodiment, computer 301 is a computing system comprising controller 210 of FIG. 2, and includes processor set 310 (including processing circuitry 320 and cache 321), communication fabric 311, volatile memory 312, persistent storage 313 (including operating system 322 and creep detection code 307, as identified above), peripheral device set 314 (including user interface (UI) device set 323, storage 324, and Internet of Things (IoT) sensor set 325), and network module 315. Remote server 304 includes remote database 330. Public cloud 305 includes gateway 340, cloud orchestration module 341, host physical machine set 342, virtual machine set 343, and container set 344.

Computer 301 may take the form of a desktop computer, laptop computer, tablet computer, smart phone, mainframe computer, quantum computer or any other form of computer or mobile device now known or to be developed in the future that is capable of running a program, accessing a network or querying a database, such as remote database 330. As is well understood in the art of computer technology, and depending upon the technology, performance of a computer-implemented method may be distributed among multiple computers and/or between multiple locations. On the other hand, in this presentation of computing environment 300, detailed discussion is focused on a single computer, specifically computer 301, to keep the presentation as simple as possible. Computer 301 may be located in a cloud, even though it is not shown in a cloud in FIG. 3. On the other hand, computer 301 is not required to be in a cloud except to any extent as may be affirmatively indicated.

Processor set 310 includes one, or more, computer processors of any type now known or to be developed in the future. Processing circuitry 320 may be distributed over multiple packages, for example, multiple, coordinated integrated circuit chips. Processing circuitry 320 may implement multiple processor threads and/or multiple processor cores. Cache 321 is memory that is located in the processor chip package(s) and is typically used for data or code that should be available for rapid access by the threads or cores running on processor set 310. Cache memories are typically organized into multiple levels depending upon relative proximity to the processing circuitry. Alternatively, some, or all, of the cache for the processor set may be located “off chip.” In some computing environments, processor set 310 may be designed for working with qubits and performing quantum computing.

Computer readable program instructions are typically loaded onto computer 301 to cause a series of operational steps to be performed by processor set 310 of computer 301 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 321 and the other storage media discussed below. The program instructions, and associated data, are accessed by processor set 310 to control and direct performance of the inventive methods. In computing environment 300, at least some of the instructions for performing the inventive methods may be stored in creep detection code 307 in persistent storage 313. In one embodiment, the creep detection code 307 is included in creep detection and reaction module 212 of FIG. 2.

Communication fabric 311 is the signal conduction path that allows the various components of computer 301 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 312 is any type of volatile memory now known or to be developed in the future. Examples include dynamic type random access memory (RAM) or static type RAM. Typically, volatile memory 312 is characterized by random access, but this is not required unless affirmatively indicated. In computer 301, the volatile memory 312 is located in a single package and is internal to computer 301, but, alternatively or additionally, the volatile memory may be distributed over multiple packages and/or located externally with respect to computer 301.

Persistent storage 313 is any form of non-volatile storage for computers that is now known or to be developed in the future. The non-volatility of this storage means that the stored data is maintained regardless of whether power is being supplied to computer 301 and/or directly to persistent storage 313. Persistent storage 313 may be a read only memory (ROM), but typically at least a portion of the persistent storage allows writing of data, deletion of data and re-writing of data. Some familiar forms of persistent storage include magnetic disks and solid state storage devices. Operating system 322 may take several forms, such as various known proprietary operating systems or open source Portable Operating System Interface-type operating systems that employ a kernel. The code included in creep detection code 307 typically includes at least some of the computer code involved in performing the inventive methods.

Peripheral device set 314 includes the set of peripheral devices of computer 301. Data communication connections between the peripheral devices and the other components of computer 301 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 323 may include components such as a display screen, speaker, microphone, wearable devices (such as goggles and smart watches), keyboard, mouse, printer, touchpad, game controllers, and haptic devices. Storage 324 is external storage, such as an external hard drive, or insertable storage, such as an SD card. Storage 324 may be persistent and/or volatile. In some embodiments, storage 324 may take the form of a quantum computing storage device for storing data in the form of qubits. In embodiments where computer 301 is required to have a large amount of storage (for example, where computer 301 locally stores and manages a large database) then this storage may be provided by peripheral storage devices designed for storing very large amounts of data, such as a storage area network (SAN) that is shared by multiple, geographically distributed computers. IoT sensor set 325 is made up of sensors that can be used in Internet of Things applications. For example, one sensor may be a thermometer and another sensor may be a motion detector.

Network module 315 is the collection of computer software, hardware, and firmware that allows computer 301 to communicate with other computers through WAN 302. Network module 315 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 315 are performed on the same physical hardware device. In other embodiments (for example, embodiments that utilize software-defined networking (SDN)), the control functions and the forwarding functions of network module 315 are performed on physically separate devices, such that the control functions manage several different network hardware devices. Computer readable program instructions for performing the inventive methods can typically be downloaded to computer 301 from an external computer or external storage device through a network adapter card or network interface included in network module 315. Network module 315 may be configured to communicate with other systems or devices, such as sensors 325, for receiving sensor measurements.

WAN 302 is any wide area network (for example, the internet) capable of communicating computer data over non-local distances by any technology for communicating computer data, now known or to be developed in the future. In some embodiments, the WAN 302 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 303 is any computer system that is used and controlled by an end user (for example, a customer of an enterprise that operates computer 301), and may take any of the forms discussed above in connection with computer 301. EUD 303 typically receives helpful and useful data from the operations of computer 301. For example, in a hypothetical case where computer 301 is designed to provide a recommendation to an end user, this recommendation would typically be communicated from network module 315 of computer 301 through WAN 302 to EUD 303. In this way, EUD 303 can display, or otherwise present, the recommendation to an end user. In some embodiments, EUD 303 may be a client device, such as thin client, heavy client, mainframe computer, desktop computer and so on.

Remote server 304 is any computer system that serves at least some data and/or functionality to computer 301. Remote server 304 may be controlled and used by the same entity that operates computer 301. Remote server 304 represents the machine(s) that collect and store helpful and useful data for use by other computers, such as computer 301. For example, in a hypothetical case where computer 301 is designed and programmed to provide a recommendation based on historical data, then this historical data may be provided to computer 301 from remote database 330 of remote server 304.

Public cloud 305 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 305 is performed by the computer hardware and/or software of cloud orchestration module 341. The computing resources provided by public cloud 305 are typically implemented by virtual computing environments that run on various computers making up the computers of host physical machine set 342, which is the universe of physical computers in and/or available to public cloud 305. The virtual computing environments (VCEs) typically take the form of virtual machines from virtual machine set 343 and/or containers from container set 344. It is understood that these VCEs may be stored as images and may be transferred among and between the various physical machine hosts, either as images or after instantiation of the VCE. Cloud orchestration module 341 manages the transfer and storage of images, deploys new instantiations of VCEs and manages active instantiations of VCE deployments. Gateway 340 is the collection of computer software, hardware, and firmware that allows public cloud 305 to communicate through WAN 302.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 306 is similar to public cloud 305, except that the computing resources are only available for use by a single enterprise. While private cloud 306 is depicted as being in communication with WAN 302, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 305 and private cloud 306 are both part of a larger hybrid cloud.

For further explanation, FIG. 4 sets forth a flow chart illustrating another exemplary method of socket downstop creep detection according to embodiments of the present disclosure. The method of FIG. 4 includes enabling 400 a current source on a creep detection circuit coupled to one or more creep detection pins within a PCB socket coupled to a module. Enabling 400 a current source on a creep detection circuit coupled to one or more creep detection pins within a PCB socket coupled to a module may be carried out by a controller (such as controller 210) by sending an instruction to turn on the current source so that current begins running through the creep detection circuit. The controller 210 may be a controller included within the PCB or separate from the PCB and within the computing system comprising the PCB.

The method of FIG. 4 also includes tracking 402 one or more resistance values associated with the creep detection circuit. Tracking 402 one or more resistance values associated with the creep detection circuit may be carried out by a controller (such as controller 210) by measuring voltage or resistance values across creep detection pins included within the module and coupled to the creep detection circuit. The creep detection pins are configured to change the resistance of creep detection circuit as the socket experiences creep. By keeping track of the resistance values associated with the creep detection circuit, the controller 210 is configured to detect when socket downstop creep occurs.

The method of FIG. 4 also includes detecting 404 socket downstop creep associated with the module based on determining that the one or more resistance values have changed by more than a threshold amount. Detecting 404 socket downstop creep associated with the module may be carried out by a controller (such as controller 210) by comparing the resistance values with historical resistance values (resistance values that were previously recorded) and determining that the one or more of the resistance values have changed by more than a threshold amount. In one embodiment, detecting socket downstop creep associated with the module is based on the one or more resistance values decreasing by a threshold amount. For example, in a creep detection circuit that has creep detection pins configured to decrease resistance as downstop creep occurs, the creep detection circuit will detect the presence of downstop creep when the resistance values in the creep detection circuit (such as the resistance across the creep detection pins) have decreased by a threshold amount.

In another embodiment, detecting socket downstop creep associated with the module is based on the one or more resistance values exceeding a threshold value. For example, in a creep detection circuit that has creep detection pins configured to move off of the contact pad (thereby causing resistance across the pins to significantly increase) as downstop creep occurs, the creep detection circuit will detect the presence of downstop creep when the resistance values in the creep detection circuit (such as the resistance across the creep detection pins) have increased beyond a threshold value. In such an example, the threshold value may be selected as a value that may only be reached if one or more creep detection pins in the creep detection circuit are no longer in contact with the corresponding contact pad in the module. In one embodiment, the method of FIG. 4 repeats periodically in order to continually or periodically check for downstop creep. In one embodiment, the period between creep detection checks is dynamically shortened (measurements are made more frequently) when resistance calculations over time for a given location are trending towards the threshold indicating creep.

For further explanation, FIG. 5 sets forth a flow chart illustrating another exemplary method of socket downstop creep detection according to embodiments of the present disclosure. The method of FIG. 4 differs from the method of FIG. 4 in that the method of FIG. 5 further includes, as part of tracking 402 one or more resistance values associated with the creep detection circuit, measuring 500 one or more voltages across the creep detection circuit. Measuring 500 one or more voltages across the creep detection circuit may be carried out by a controller (such as controller 210) by taking voltage measurements using a voltage measuring device included within the creep detection circuit.

The method of FIG. 5 also includes, as part of tracking 402 one or more resistance values 501 associated with the creep detection circuit, calculating 502, based on the one or more voltages, the one or more resistance values associated with the creep detection circuit. Calculating 502 the one or more resistance values associated with the creep detection circuit may be carried out by a controller (such as controller 210) by dividing the measured voltage values by the known current value that is being output by the current source within the creep detection circuit. The calculated resistance values 501 are a measurement of the electrical resistance across the two creep detection pins included within the module and coupled to the creep detection circuit.

The method of FIG. 5 also includes, as part of tracking 402 one or more resistance values associated with the creep detection circuit, storing 504 the one or more resistance values each time they are calculated. Storing 504 the one or more resistance values 501 each time they are calculated may be carried out by a controller (such as controller 210) by storing the resistance values 501 in a database (such as database 220 in FIG. 2) or other memory coupled to the controller. By storing each resistance value 501 within memory, the values may be compared with one another over time in order to detect downstop creep. In one embodiment, a time-zero resistance value is stored in the database, where the time-zero resistance value is either the first resistance value calculated, or the first resistance value calculated after a predetermined amount of time to account for initial allowable creep upon module installation. In such an embodiment where one of the resistance values stored within the database is indicated as a time-zero value, each new resistance value is compared with the time-zero value when determining whether creep has occurred within the socket.

The method of FIG. 5 also includes generating 506 a strain map across the module using the one or more resistance values. Generating 506 a strain map 507 across the module using the one or more resistance values may be carried out by a controller (such as controller 210) by including, in a representation of the layout of the socket, indications how much downstop creep each section or area of the socket (corresponding with each creep detection circuit included in the socket) is experiencing. In another embodiment, the strain map also indicates the rate at which downstop creep is increasing for each area of the socket.

The method of FIG. 5 also includes generating 508 a notification responsive to detecting socket downstop creep associated with the module. Generating 508 a notification 509 responsive to detecting socket downstop creep associated with the module may be carried out by a controller (such as controller 210) by creating a notification 509 comprising an indication of socket downstop creep and information identifying both the socket and an area of the socket that is experiencing socket downstop creep. The notification 509 may be stored in memory (such as database 220, sent to an administrator of a system comprising the PCB and the controller 210, or stored in a remote system. In one embodiment, the notification is a call home signal or a system reference code (SRC).

The method of FIG. 5 also includes shifting 510 workload away from an area of the socket experiencing socket downstop creep. Shifting 510 workload away from an area of the socket experiencing socket downstop creep may be carried out by a controller (such as controller 210) responsive to the controller detecting the presence of socket downstop creep. Shifting 510 workload includes sending workload to a different location than the area of the socket that is experiencing downstop creep. In one embodiment where the module coupled to the socket includes a processor having multiple cores, the workload may be shifted from the core most closely proximate to the area of the socket experiencing downstop creep to another core on the processor that is further away from the area experiencing downstop creep. In another embodiment, where the module coupled to the socket includes multiple processors, the workload given to the processor proximate to the area experiencing downstop creep may be shifted to another processor on the module (such as a processor that is further away from the area experiencing downstop creep). In another embodiment, the workload being sent to the module experiencing downstop creep may be shifted to a different module (whether on the same socket or on a separate socket).

In view of the explanations set forth above, readers will recognize that the benefits of socket downstop creep detection according to embodiments of the present disclosure include:
Increasing socket reliability by detecting downstop creep, preventing future errors or system failures from occurring.
Increasing component longevity by detecting downstop creep, allowing for components to be serviced prior to becoming damaged.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

It will be understood from the foregoing description that modifications and changes may be made in various embodiments of the present disclosure without departing from its true spirit. The descriptions in this specification are for purposes of illustration only and are not to be construed in a limiting sense. The scope of the present disclosure is limited only by the language of the following claims.

What is claimed is:

1. An apparatus comprising:
a module including multiple contact pads; and
a printed circuit board (PCB) comprising:
a socket for receiving the module, wherein the socket includes a plurality of downstops and a plurality of pins configured to contact the multiple contact pads of the module when the module is coupled to the socket; and
a creep detection circuit configured to detect a threshold amount of creep within the socket, wherein one or more of the plurality of pins are creep detection pins coupled to the creep detection circuit.

2. The apparatus of claim 1, wherein the module includes one or more connections between one or more contact pads contacting the creep detection pins.

3. The apparatus of claim 1, wherein the plurality of pins includes the creep detection pins and one or more contact pins configured to route signals between the module and the PCB.

4. The apparatus of claim 3, wherein the creep detection pins are structurally different from the one or more contact pins.

5. The apparatus of claim 1, wherein the creep detection pins are configured to increase a surface area of the creep detection pins contacting one or more contact pads when the socket experiences creep.

6. The apparatus of claim 1, wherein each of the creep detection pins is configured to slip off of a contact pad when the socket experiences the threshold amount of creep.

7. The apparatus of claim 1, wherein downstop creep is measured by the creep detection circuit based on resistance measurements associated with the creep detection circuit.

8. A system comprising:
a module including multiple contact pads;
a printed circuit board (PCB) comprising:
a socket for receiving the module, wherein the socket includes a plurality of pins configured to contact the multiple contact pads of the module when the module is coupled to the socket; and
a creep detection circuit configured to detect a threshold amount of creep within the socket, wherein one or more of the plurality of pins are creep detection pins coupled to the creep detection circuit;
a controller configured to receive data from the creep detection circuit; and
a database configured to store data related to the creep detection circuit.

9. The system of claim 8, wherein the data stored in the database comprises resistance measurements associated with the creep detection circuit.

10. The system of claim 8, wherein the PCB includes multiple creep detection circuits associated with the socket, wherein each creep detection circuit is configured to monitor downstop creep in an area of the socket proximate to each creep detection circuit.

11. A method for socket downstop creep detection using a creep detection and reaction module, the method comprising:
enabling a current source on a creep detection circuit coupled to one or more creep detection pins within a printed circuit board (PCB) socket coupled to a module;
tracking one or more resistance values associated with the creep detection circuit; and
detecting socket downstop creep associated with the module based on determining that the one or more resistance values have changed by more than a threshold amount.

12. The method of claim 11, wherein tracking the one or more resistance values includes, iteratively at a set interval:
measuring one or more voltages across the creep detection circuit; and
calculating, based on the one or more voltages, the one or more resistance values associated with the creep detection circuit.

13. The method of claim 12, further comprising storing the one or more resistance values each time they are calculated.

14. The method of claim 11, wherein determining that the one or more resistance values have changed by more than the threshold amount includes comparing the one or more resistance values to previously recorded resistance values associated with the creep detection circuit.

15. The method of claim 11, further comprising generating a notification responsive to detecting socket downstop creep associated with the module.

16. The method of claim 11, further comprising, responsive to detecting the socket downstop creep, shifting workload away from an area experiencing the socket downstop creep.

17. The method of claim 16, wherein the workload is shifted to one of: another core on the module, another processor on the module, and another module.

18. The method of claim 11, further comprising generating a strain map across the module using the one or more resistance values.

19. The method of claim 11, wherein detecting socket downstop creep associated with the module is based on the one or more resistance values decreasing by a threshold amount.

20. The method of claim 11, wherein detecting socket downstop creep associated with the module is based on the one or more resistance values exceeding a threshold value.
